(19) United States
(12) Patent Application Publication
(10) Pub. No.: US 2024/0260270 A1
(43) Pub. Date: Aug. 1, 2024

(54) FIELD EFFECT TRANSISTOR AND SEMICONDUCTOR DEVICE INCLUDING THE SAME

(71) Applicant: Samsung Electronics Co., Ltd., Suwon-si (KR)

(72) Inventors: Taeyoon HONG, Suwon-si (KR); Janggn YUN, Suwon-si (KR); Hyunho KIM, Suwon-si (KR); Jeehoon HAN, Suwon-si (KR)

(73) Assignee: Samsung Electronics Co., Ltd., Suwon-si (KR)

(21) Appl. No.: 18/508,530

(22) Filed: Nov. 14, 2023

(30) Foreign Application Priority Data
Jan. 27, 2023 (KR) 10-2023-0011220

(51) Int. Cl. H10B 43/27; H10B 41/27; H10B 41/35; H10B 41/50; H10B 43/35; H10B 43/50

(52) U.S. Cl. CPC H10B 43/27; H10B 41/27; H10B 41/35; H10B 41/50; H10B 43/35; H10B 43/50

(57) ABSTRACT

A field effect transistor includes a horizontal channel layer, an interlayer insulating layer on the horizontal channel layer, a gate electrode layer on the interlayer insulating layer, a first vertical channel structure passing through the gate electrode layer and the interlayer insulating layer in a vertical direction, in contact with the horizontal channel layer, and connected to one of a source terminal or a drain terminal, and a second vertical channel structure apart from the first vertical channel structure in a horizontal direction, passing through the gate electrode layer and the interlayer insulating layer in the vertical direction, in contact with the horizontal channel layer, and connected to another of the source terminal or the drain terminal.

### CROSS-REFERENCE TO RELATED APPLICATION

This application is based on and claims priority under 35 U.S.C. § 119 to Korean Patent Application No. 10-2023-0011220, filed on Jan. 27, 2023, in the Korean Intellectual Property Office, the disclosure of which is incorporated by reference herein in its entirety.

### BACKGROUND

The inventive concept relates to a field effect transistor (FET) and a semiconductor device including the same.

A transistor is or includes a semiconductor element configured to perform an electrical switching function and may be implemented in various integrated circuit (IC) devices including a memory, a driving IC, a logic device, etc. In order to increase the degree of integration in IC devices, the space occupied by transistors included in IC devices has been drastically reduced. Therefore, research has been conducted to maintain the performance of a transistor while reducing the size of the transistor.

### SUMMARY

Various example embodiments may provide a field effect transistor having improved electrical reliability and/or spatial efficiency.

Alternatively or additionally, various example embodiments may provide a semiconductor device including three-dimensionally arranged memory cells, the semiconductor device having a structure for improving the electrical characteristic and the spatial efficiency.

According to some example embodiments, there is provided a field effect transistor including a horizontal channel layer, an interlayer insulating layer on the horizontal channel layer, a gate electrode layer on the interlayer insulating layer, a first vertical channel structure passing through the gate electrode layer and the interlayer insulating layer in a vertical direction and in contact with the horizontal channel layer and connected to a one of a source terminal or a drain terminal, and a second vertical channel structure apart from the first vertical channel structure in a horizontal direction, passing through the gate electrode layer and the interlayer insulating layer in the vertical direction and in contact with the horizontal channel layer, and connected to another of the source terminal or the drain terminal.

Alternatively or additionally according to some example embodiments, there is provided a semiconductor device including a semiconductor substrate having a memory cell region and a connection region, a gate stack including a plurality of word line gate layers and a plurality of insulating layers, which extend in a horizontal direction and are alternately stacked in a vertical direction on a main surface of the semiconductor substrate, the gate stack having a stair structure including a plurality of pad portions in the connection region, an insulating block on the gate stack, a horizontal channel layer on the insulating block in the connection region, an interlayer insulating layer on the horizontal channel layer, a plurality of upper gate layers in the connection region, extending in a first horizontal direction on the interlayer insulating layer, and arranged in parallel with each other in a second horizontal direction crossing the first horizontal direction, and a plurality of vertical channel structures passing through the interlayer insulating layer and the plurality of upper gate layers and contacting the horizontal channel layer.

Alternatively or additionally according to some example embodiments, there is provided a semiconductor device including a semiconductor substrate having a memory cell region and a connection region, a gate stack including a plurality of word line gate layers and a plurality of insulating layers, which extend in a horizontal direction and are alternately stacked in a vertical direction on a main surface of the semiconductor substrate, the gate stack having a stair structure including a plurality of pad portions, in the connection region, an insulating block on the gate stack, a horizontal channel layer on the insulating block in the connection region, an interlayer insulating layer on the horizontal channel layer, a plurality of upper gate layers extending on the interlayer insulating layer in the connection region in a first horizontal direction and arranged in parallel with each other in a second horizontal direction crossing the first horizontal direction, a string selection line gate layer at a same vertical level as the plurality of upper gate layers on the insulating block in the memory cell region, and a plurality of vertical channel structures passing through the interlayer insulating layer and the plurality of upper gate layers and contacting the horizontal channel layer.

### BRIEF DESCRIPTION OF THE DRAWINGS

Various example embodiments will be more clearly understood from the following detailed description taken in conjunction with the accompanying drawings in which:

FIG. 1A is a plan view for describing a field effect transistor according to some example embodiments;

FIG. 1B is a cross-sectional view of the field effect transistor taken along line A1-A1′ of FIG. 1A;

FIG. 1C is an equivalent circuit diagram of a field effect transistor according to some example embodiments;

FIG. 1D is an enlarged view of a region indicated as “EX1” in FIG. 1B;

FIG. 2A is a plan view for describing a field effect transistor according to some example embodiments;

FIG. 2B is a cross-sectional view of the field effect transistor taken along line A2-A2′ of FIG. 2A;

FIG. 3A is a plan view for describing a field effect transistor according to some example embodiments;

FIG. 3B is a cross-sectional view of the field effect transistor taken along line A3-A3′ of FIG. 3A;

FIG. 4A is a plan view for describing a field effect transistor according to some example embodiments;

FIG. 4B is a cross-sectional view of the field effect transistor taken along line A4-A4′ of FIG. 4A;

FIG. 5A is a plan view for describing a field effect transistor according to some example embodiments;

FIG. 5B is a cross-sectional view of the field effect transistor taken along line A5-A5′ of FIG. 5A;

FIG. 6 is a block diagram of a semiconductor device according to some example embodiments;

FIG. 7 is an equivalent circuit diagram of a memory cell array of a semiconductor device according to some example embodiments;

FIG. 8 is a perspective view illustrating representative components of a semiconductor device according to some example embodiments;

FIG. 9 is a plan view of a semiconductor device according to some example embodiments;

FIG. 10 is a cross-sectional view of the semiconductor device taken along line B1-B1′ of FIG. 9;

FIG. 11 is an enlarged view of a region indicated as “VM1” in FIG. 10;

FIG. 12 is an enlarged view of a region indicated as “PM1” in FIG. 9;

FIG. 13 is a cross-sectional view of the semiconductor device taken along line B2-B2′ of FIG. 12;

FIG. 14 is an enlarged view of a region indicated as “VM2” in FIG. 13; and

FIGS. 15A to 15E are cross-sectional views for describing a method of manufacturing a field effect transistor, according to some example embodiments.

### DETAILED DESCRIPTION OF VARIOUS EXAMPLE EMBODIMENTS

Hereinafter, some example embodiments are described in detail with reference to the accompanying drawings. For the same elements in the drawings, the same reference numerals are used, and the same descriptions are not repeated.

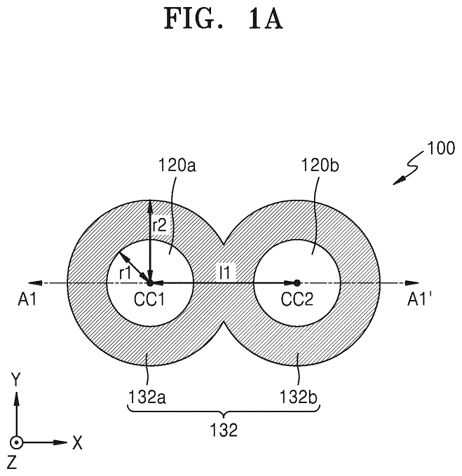

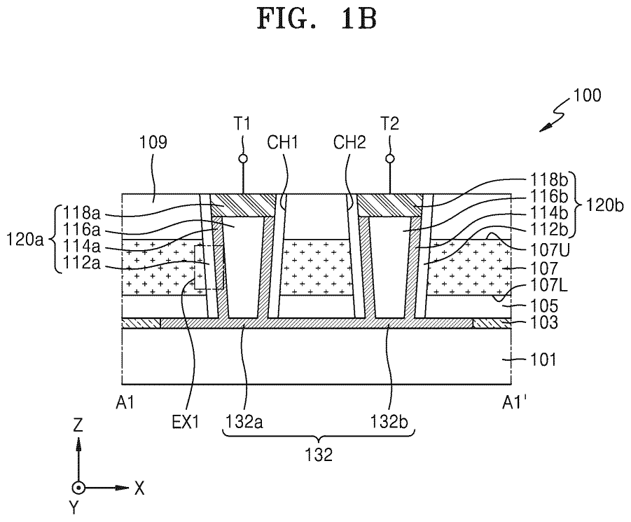

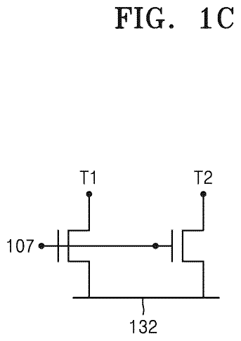

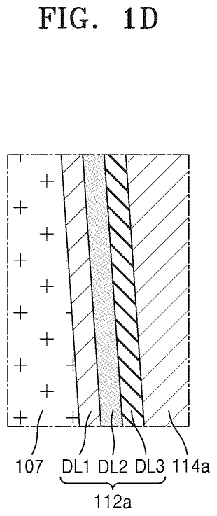

FIG. 1A is a plan view for describing a field effect transistor 100 according to some example embodiments. FIG. 1B is a cross-sectional view of the field effect transistor 100 taken along line A1-A1′ of FIG. 1A. FIG. 1C is an equivalent circuit diagram of the field effect transistor 100 according to some example embodiments. FIG. 1D is an enlarged view of a region indicated as “EX1” in FIG. 1B.

Referring to FIGS. 1A to 1D, a horizontal channel layer 132 and a sacrificial insulating layer 103 may be arranged on a lower insulating layer 101. According to some example embodiments, an interlayer insulating layer 105 may cover the horizontal channel layer 132 and the sacrificial insulating layer 103, and a gate electrode layer 107 and an upper insulating layer 109 may be sequentially arranged on the interlayer insulating layer 105.

According to some example embodiments, the lower insulating layer 101 may include oxide, nitride, or a combination thereof. According to some example embodiments, the sacrificial insulating layer 103 may include a material having an etch selectivity with the interlayer insulating layer 105; e.g., the sacrificial insulating layer 103 may etch faster than the interlayer insulating layer. According to some example embodiments, the sacrificial insulating layer 103 may include silicon nitride, and the interlayer insulating layer 105 may include silicon oxide. According to some example embodiments, the gate electrode layer 107 may include a conductive material. For example, the conductive material may include polysilicon such as doped polysilicon. According to some example embodiments, the upper insulating layer 109 may include oxide, nitride, or a combination thereof.

According to some example embodiments, a first vertical channel structure 120a and a second vertical channel structure 120b passing through the interlayer insulating layer 105, the gate electrode layer 107, and the upper insulating layer 109 in a vertical direction (a Z direction) may be arranged on the horizontal channel layer 132. According to some example embodiments, the first vertical channel structure 120a and the second vertical channel structure 120b may be apart from each other in a horizontal direction (an X direction and/or a Y direction). According to some example embodiments, each of the first vertical channel structure 120a and the second vertical channel structure 120b may contact the horizontal channel layer 132.

According to some example embodiments, the gate electrode layer 107 may have a first surface 107L and a second surface 107U facing each other. For example, the first surface 107L of the gate electrode layer 107 may face an upper surface of the horizontal channel layer 132 with the interlayer insulating layer 105 therebetween. For example, the first vertical channel structure 120a and the second vertical channel structure 120b may contact the horizontal channel layer 132 on the first surface 107L of the gate electrode layer 107.

According to some example embodiments, the horizontal channel layer 132 may overlap the first vertical channel structure 120a and the second vertical channel structure 120b in the vertical direction (the Z direction). As illustrated in FIG. 1A, in a plan view, the first vertical channel structure 120a and the second vertical channel structure 120b may be included in the horizontal channel layer 132. For example, a projection of the first vertical channel structure 120a in the vertical direction (the Z direction) and a projection of the second vertical channel structure 120b in the vertical direction (the Z direction) may be arranged in the horizontal channel layer 132.

According to some example embodiments, the horizontal channel layer 132 may include a first portion 132a overlapping the first vertical channel structure 120a in the vertical direction (the Z direction) and a second portion 132b overlapping the second vertical channel structure 120b in the vertical direction (the Z direction).

According to some example embodiments, the first portion 132a of the horizontal channel layer 132 may have a greater planar area than the first vertical channel structure 120a, and in a plan view, the first vertical channel structure 120a may be arranged in the first portion 132a of the horizontal channel layer 132. According to some example embodiments, the first portion 132a of the horizontal channel layer 132 may have a greater planar area than a lower surface of the first vertical channel structure 120a.

According to some example embodiments, the second portion 132b of the horizontal channel layer 132 may have a greater area or greater planar area than the second vertical channel structure 120b, and in a plan view, the second vertical channel structure 120b may be arranged in the second portion 132b of the horizontal channel layer 132. According to some example embodiments, the second portion 132b of the horizontal channel layer 132 may have a greater area or greater planar area than a lower surface of the second vertical channel structure 120b.

According to some example embodiments, in a plan view, the first vertical channel structure 120a and the first portion 132a of the horizontal channel layer 132 may have a rounded shape such as a circular shape, such as a concentric circular shape having a first center CC1, and the second vertical channel structure 120b and the second portion 132b of the horizontal channel layer 132 may have rounded shape such as a circular shape such as a concentric circular shape having a second center CC2. For example, in a plan view, each of the first vertical channel structure 120a and the second vertical channel structure 120b may have a first radius r1, and each of the first portion 132a and the second portion 132b of the horizontal channel layer 132 may have a second radius r2 that is greater than the first radius r1. In this case, the horizontal channel layer 132 may have a shape in which a circle of the first portion 132a and a circle of the second portion 132b partially overlap each other. For example, a first distance 11 between the first center CC1 and the second center CC2 may be greater than a sum of the radius of the first vertical channel structure 120a and the radius of the second vertical channel structure 120b and may be less than a sum of the radius of the first portion 132a of the horizontal channel layer 132 and the radius of the second portion 132b of the horizontal channel layer 132. For example, in a plan view, the horizontal channel layer 132 may be partially arranged between the first vertical channel structure 120a and the second vertical channel structure 120b, and accordingly, the first vertical channel structure 120a may be connected to the second vertical channel structure 120b through the horizontal channel layer 132. For example, the horizontal channel layer 132 and the first vertical channel structure 120a and the second vertical channel structure 120b contacting the upper surface of the horizontal channel layer 132 may have a “U” or a sharped-corned “U” or an upside-down “x”-shaped structure.

According to some example embodiments, the horizontal channel layer 132 may extend in a direction in which the first vertical channel structure 120a and the second vertical channel structure 120b are arranged. Referring to FIG. 1A, the first vertical channel structure 120a and the second vertical channel structure 120b may be arranged in a first horizontal direction (the X direction), and in this case, the horizontal channel layer 132 may extend in the first horizontal direction (the X direction) and may overlap the first vertical channel structure 120a and the second vertical channel structure 120b in the vertical direction (the Z direction).

The first vertical channel structure 120a may be arranged in a first channel hole CH1 passing through the interlayer insulating layer 105, the gate electrode layer 107, and the upper insulating layer 109 in the vertical direction (the Z direction). According to some example embodiments, the first vertical channel structure 120a may include a first gate dielectric layer 112a, a first channel area 114a, a first buried insulating layer 116a, and a first conductive plug 118a. According to some example embodiments, the first gate dielectric layer 112a and the first channel area 114a may be sequentially arranged on an inner wall of the first channel hole CH1. The first gate dielectric layer 112a may be conformally arranged on the inner wall of the first channel hole CH1 on the horizontal channel layer 132, and the first channel area 114a may conformally cover the first gate dielectric layer 112a by partially filling a space limited by the first gate dielectric layer 112a on the horizontal channel layer 132. The first buried insulating layer 116a may fill a remaining space of the first channel hole CH1 on the horizontal channel layer 132. The first conductive plug 118a contacting the first channel area 114a and blocking an entrance of the first channel hole CH1 may be arranged above the first channel hole CH1. According to some example embodiments, the first buried insulating layer 116a may be omitted, and in this case, the first channel area 114a may have a pillar structure having no inner space.

According to some example embodiments, an upper end of the first channel area 114a may contact the first conductive plug 118a, and a lower end of the first channel area 114a may contact the horizontal channel layer 132. According to some example embodiments, the first channel area 114a may have an integral structure with the horizontal channel layer 132.

As illustrated in FIG. 1D, the first gate dielectric layer 112a may include a blocking dielectric layer DL1, a charge storage layer DL2, and a tunneling dielectric layer DL3 sequentially stacked on the inner wall of the first channel hole CH1. The relative thickness of the blocking dielectric layer DL1, the charge storage layer DL2, and the tunneling dielectric layer DL3 is not limited to the relative thickness illustrated in FIG. 1D and may be variously modified. The relative thickness of the blocking dielectric layer DL1, the charge storage layer DL2, and the tunneling dielectric layer DL3 may be the same as each other, or at least one thickness may be different than (greater than or less than) at least another one.

According to some example embodiments, the blocking dielectric layer DL1 may include silicon oxide, silicon nitride, or metal oxide having a greater dielectric constant than silicon oxide. The metal oxide may include hafnium oxide, aluminum oxide, zirconium oxide, tantalum oxide, or a combination thereof. According to some example embodiments, the charge storage layer DL2 may be or may include an area in which electrons having passed through the tunneling dielectric layer DL3 from the first channel area 114a are stored and may include at least one of silicon nitride, boron nitride, silicon boron nitride, or polysilicon doped with a dopant. According to some example embodiments, the tunneling dielectric layer DL3 may include at least one of silicon oxide, hafnium oxide, aluminum oxide, zirconium oxide, tantalum oxide, or the like.

According to some example embodiments, the first channel area 114a may include polysilicon such as doped polysilicon. According to some example embodiments, the first buried insulating layer 116a may include silicon oxide, silicon nitride, silicon oxynitride, or a combination thereof. According to some example embodiments, the first conductive plug 118a may include a conductive material, for example, metal, conductive metal nitride, polysilicon doped with a dopant, or a combination thereof. Examples of the metal included in the first conductive plug 118a may include one or more of tungsten, nickel, cobalt, tantalum, and the like.

The second vertical channel structure 120b may be arranged in a second channel hole CH2 apart from the first channel hole CH1 in the horizontal direction (the X direction and/or the Y direction) and passing through the interlayer insulating layer 105, the gate electrode layer 107, and the upper insulating layer 109 in the vertical direction (the Z direction). According to some example embodiments, the second vertical channel structure 120b may include a second gate dielectric layer 112b, a second channel area 114b, a second buried insulating layer 116b, and a second conductive plug 118b.

According to some example embodiments, the second gate dielectric layer 112b, the second channel area 114b, the second buried insulating layer 116b, and the second conductive plug 118b may respectively have substantially the same structure and include substantially the same material as the first gate dielectric layer 112a, the first channel area 114a, the first buried insulating layer 116a, and the first conductive plug 118a of the first vertical channel structure 120a described above. For example, the second gate dielectric layer 112b may include the blocking dielectric layer DL1, the charge storage layer DL2, and the tunneling dielectric layer DL3.

According to some example embodiments, an upper end of the second channel area 114b may contact the second conductive plug 118b, and a lower end of the second channel area 114b may contact the horizontal channel layer 132. According to some example embodiments, the second channel area 114b may have an integral structure with the horizontal channel layer 132.

According to some example embodiments, the first channel area 114a and the second channel area 114b may be formed together with the horizontal channel layer 132 in a single process. In this case, the horizontal channel layer 132 and the first channel area 114a and the second channel area 114b each contacting the upper surface of the horizontal channel layer 132 may have an integral (or homogenous) structure. For example, the first channel area 114a, the second channel area 114b, and the horizontal channel layer 132 may form one channel structure including a vertical extension portion and a horizontal extension portion.

According to some example embodiments, the first conductive plug 118a and the second conductive plug 118b may have the same conductivity type. For example, the first conductive plug 118a and the second conductive plug 118b may include polysilicon doped with a dopant of the same conductivity type. According to some example embodiments, the first conductive plug 118a and the second conductive plug 118b may include polysilicon doped with a p-type dopant. For example, the p-type dopant may be selected from boron (B) and gallium (Ga). According to some example embodiments, the first conductive plug 118a and the second conductive plug 118b may include polysilicon doped with an n-type dopant. For example, the n-type dopant may be selected from phosphorous (P), arsenic (As), and antimony (Sb). In some example embodiments, the first conductive plug 118a and the second conductive plug 118b may include n-type dopants at a first concentration and p-type dopants at a second concentration, much less than the first concentration. Alternatively in some example embodiments the first conductive plug 118a and the second conductive plug 118b may include p-type dopants at a first concentration and n-type dopants at a second concentration, much less than the first concentration.

According to some example embodiments, the first conductive plug 118a may be a source area and may be connected to one of a source terminal or a drain terminal, such as to a source terminal T1. According to some example embodiments, the second conductive plug 118b may be a drain area and may be connected to another of the source terminal and the drain terminal, such as a drain terminal T2.

According to some example embodiments, both of the first conductive plug 118a and the second conductive plug 118b may be arranged on the second surface 107U of the gate electrode layer 107, and both of the source terminal T1 and the drain terminal T2 may be arranged at one side with respect to the gate electrode layer 107, and thus, the spatial efficiency may be improved in a gate all around (GAA) structure in which a vertical channel structure penetrates a gate electrode.

According to a GAA vertical channel structure according to the related art, a source area may be arranged on a surface of a gate electrode and a drain area may be arranged on another surface of the gate electrode. In this case, a wire may be arranged on each of both surfaces of the gate electrode to increase the wire complexity.

In the field effect transistor 100 according to some example embodiments, a channel length may be increased through the horizontal channel layer 132 arranged on the first surface 107L of the gate electrode layer 107, and thus, electrical reliability may be improved, and the first conductive plug 118a and the second conductive plug 118b may be arranged on the second surface 107U of the gate electrode layer 107, and thus, spatial efficiency may be increased.

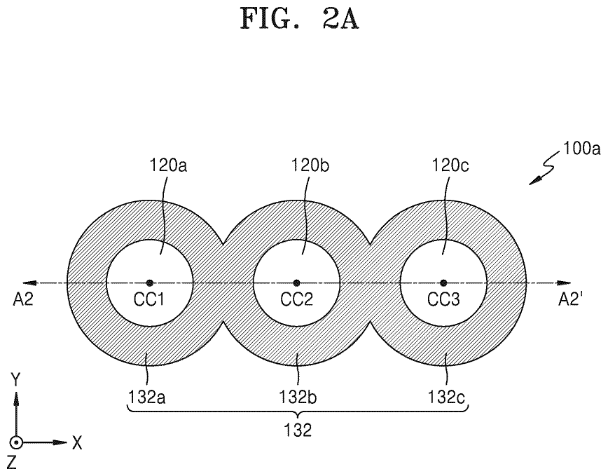

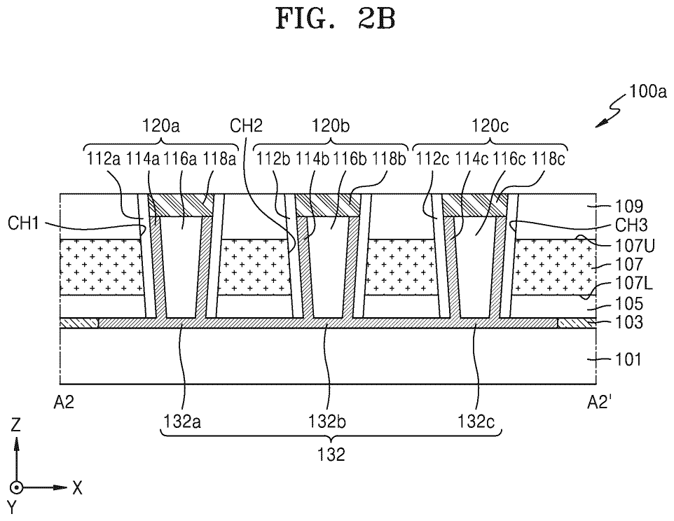

FIG. 2A is a plan view for describing a field effect transistor 100a according to some example embodiments. FIG. 2B is a cross-sectional view of the field effect transistor 100a taken along line A2-A2′ of FIG. 2A. In some example embodiments as in FIGS. 2A and 2B, the field effect transistor 100a may include a third vertical channel structure 120c.

Referring to FIGS. 2A and 2B, the field effect transistor 100a may include the third vertical channel structure 120c apart from the first vertical channel structure 120a and the second vertical channel structure 120b in the horizontal direction (the X direction and/or the Y direction) and passing through the interlayer insulating layer 105, the gate electrode layer 107, and the upper insulating layer 109 in the vertical direction (the Z direction). According to some example embodiments, the third vertical channel structure 120c may contact the horizontal channel layer 132.

According to some example embodiments, the horizontal channel layer 132 may include a third portion 132c overlapping the third vertical channel structure 120c in the vertical direction (the Z direction), and the third vertical channel structure 120c may contact the third portion 132c of the horizontal channel layer 132. According to some example embodiments, the third portion 132c of the horizontal channel layer 132 may have a greater planar area than the third vertical channel structure 120c in a plan view. According to some example embodiments, the third vertical channel structure 120c may be arranged in the third portion 132c of the horizontal channel layer 132 in the plan view.

According to some example embodiments, in the plan view, the third vertical channel structure 120c and the third portion 132c of the horizontal channel layer 132 may have a concentric circular shape having a third center CC3. For example, in the plan view, a radius of the third portion 132c of the horizontal channel layer 132 may be greater than a radius of the third vertical channel structure 120c.

According to some example embodiments, the third vertical channel structure 120c may have the same radius as the first vertical channel structure 120a and the second vertical channel structure 120b in the plan view, but example embodiments are not limited thereto. For example, the first to third vertical channel structures 120a, 120b, and 120c may have circular shapes having different radiuses from each other in the plan view.

According to some example embodiments, the horizontal channel layer 132 may have a shape in which a circle of the first portion 132a, a circle of the second portion 132b, and a circle of the third portion 132c kiss or partially overlap each other. According to some example embodiments, the field effect transistor 100a may include the third vertical channel structure 120c, and the horizontal channel layer 132 may include the third portion 132c overlapping the third vertical channel structure 120c in the vertical direction (the Z direction), and thus, a planar area of the horizontal channel layer 132 may be increased.

According to some example embodiments, the first to third vertical channel structures 120a, 120b, and 120c may be arranged in the first horizontal direction (the X direction). For example, the horizontal channel layer 132 may have a shape in which a circle of the first portion 132a and a circle of the second portion 132b kiss or at least partially overlap each other, and the circle of the second portion 132b and a circle of the third portion 132c kiss or at least partially overlap each other. For example, the horizontal channel layer 132 may extend in the direction (for example, the X direction) in which the first to third vertical channel structures 120a, 120b, and 120c are arranged.

In FIG. 2A, it is illustrated that the first to third vertical channel structures 120a to 120c are arranged in the first horizontal direction (the X direction). However, the arrangement structure of the first to third vertical channel structures 120a to 120c is not limited thereto. For example, at least one of the first to third vertical channel structures 120a, 120b, and 120c may be arranged apart from another vertical channel structure in a second horizontal direction (the Y direction). For example, a line connecting the first center CC1, the second center CC2, and the third center CC3 may form a triangle such as an equilateral triangle. According to some example embodiments, the horizontal channel layer 132 may have a shape in which a circle of the first portion 132a and a circle of the second portion 132b overlap each other, the circle of the second portion 132b and a circle of the third portion 132c overlap each other, and the circle of the third portion 132c and the circle of the first portion 132a overlap each other.

The third vertical channel structure 120c may be arranged in a third channel hole CH3 apart from the first channel hole CH1 and the second channel hole CH2 in the horizontal direction (the X direction and/or the Y direction) and passing through the interlayer insulating layer 105, the gate electrode layer 107, and the upper insulating layer 109 in the vertical direction (the Z direction). According to some example embodiments, the third vertical channel structure 120c may include a third gate dielectric layer 112c, a third channel area 114c, a third buried insulating layer 116c, and a third conductive plug 118c.

According to some example embodiments, the third gate dielectric layer 112c, the third channel area 114c, the third buried insulating layer 116c, and the third conductive plug 118c may respectively have substantially the same structure and include substantially the same material as the first gate dielectric layer 112a, the first channel area 114a, the first buried insulating layer 116a, and the first conductive plug 118a of the first vertical channel structure 120a described above. For example, the third gate dielectric layer 112c may include the blocking dielectric layer DL1, the charge storage layer DL2, and the tunneling dielectric layer DL3.

According to some example embodiments, an upper end of the third channel area 114c may contact the third conductive plug 118c, and a lower end of the third channel area 114c may contact the horizontal channel layer 132. According to some example embodiments, the third channel area 114c may have an integral structure or a homogenous structure with the horizontal channel layer 132. For example, the first channel area 114a, the second channel area 114b, the third channel area 114c, and the horizontal channel layer 132 may form one (one contiguous) channel structure including a vertical extension portion and a horizontal extension portion.

According to some example embodiments, the third conductive plug 118c may be arranged at the same vertical level as the first conductive plug 118a and the second conductive plug 118b. For example, the first to third conductive plugs 118a, 118b, and 118c may be arranged at a higher vertical level than the second surface 107U of the gate electrode layer 107, and the first channel area 114a, the second channel area 114b, and the third channel area 114c may be connected to the horizontal channel layer 132 arranged at a lower vertical level than the first surface 107L of the gate electrode layer 107. The term “vertical level” used in this specification denotes a distance in the vertical direction (the Z direction or a −Z direction) from the first surface 107L of the gate electrode layer 107.

According to some example embodiments, the third conductive plug 118c may have the same conductivity type as the first conductive plug 118a and the second conductive plug 118b. For example, the first to third conductive plugs 118a to 118c may include polysilicon doped with a dopant of the same conductivity type. For example, the first to third conductive plugs 118a to 118c may include polysilicon doped with a p-type dopant, and the p-type dopant may be selected from B and/or Ga. On the contrary, the first to third conductive plugs 118a to 118c may include polysilicon doped with an n-type dopant, and the n-type dopant may be selected from at least one of P, As, and Sb. In this case, the third conductive plug 118c may be a drain area and may be connected to a source terminal or a drain terminal (not shown). For example, the field effect transistor 110a may include two or more drain areas or two or more source terminals.

According to some example embodiments, the third conductive plug 118c may have a conductivity type that is the opposite to a conductivity type of the first conductive plug 118a and the second conductive plug 118b. For example, the first conductive plug 118a and the second conductive plug 118b may include polysilicon doped with a dopant having a first conductivity type, and the third conductive plug 118c may include polysilicon doped with a dopant having a second conductivity type that is the opposite to the first conductivity type. For example, the first and second conductive plugs 118a and 118b may include polysilicon doped with an n-type dopant without or with a much smaller concentration of p-type dopants, and the third conductive plug 118c may include polysilicon doped with a p-type dopant without or with a much smaller concentration of n-type dopants. On the contrary, the first and second conductive plugs 118a and 118b may include polysilicon doped with a p-type dopant without or with a much smaller concentration of n-type dopants, and the third conductive plug 118c may include polysilicon doped with an n-type dopant without or with a much smaller concentration of p-type dopants. In this case, the third conductive plug 118c may be connected to a body terminal, and the third vertical channel structure 120c may perform a function of a body contact configured to alleviate or improve upon the body effect.

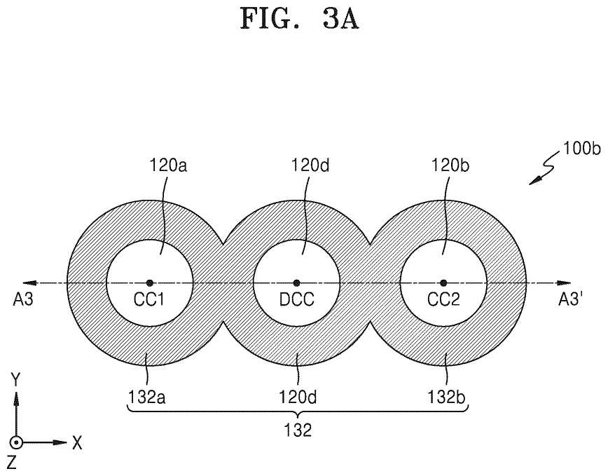

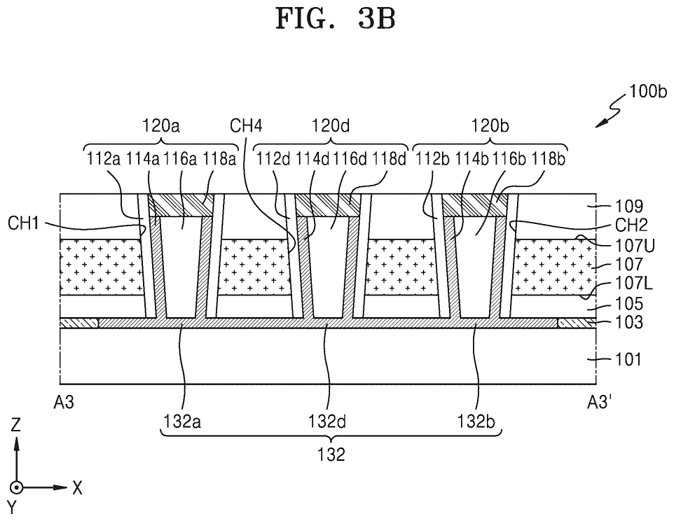

FIG. 3A is a plan view for describing a field effect transistor 100b according to some example embodiments. FIG. 3B is a cross-sectional view of the field effect transistor 100b taken along line A3-A3′ of FIG. 3A. In FIGS. 3A and 3B, the field effect transistor 100b further includes a dummy vertical channel structure 120d. In some example embodiments, the dummy vertical channel structure 120d is not electrically active during operation of the field effect transistor 100b. For example, the dummy vertical channel structure 120d may be floating during the operation of the field effect transistor 120d.

Referring to FIGS. 3A and 3B, the field effect transistor 100b may include the dummy vertical channel structure 120d arranged between the first vertical channel structure 120a and the second vertical channel structure 120b to be apart from the first vertical channel structure 120a and the second vertical channel structure 120b and passing through the interlayer insulating layer 105, the gate electrode layer 107, and the upper insulating layer 109 in the vertical direction (the Z direction).

According to some example embodiments, the horizontal channel layer 132 may include a fourth portion 132d overlapping the dummy vertical channel structure 120d in the vertical direction (the Z direction), and the dummy vertical channel structure 120d may contact the fourth portion 132d of the horizontal channel layer 132. According to some example embodiments, the fourth portion 132d of the horizontal channel layer 132 may have a greater planar area than the dummy vertical channel structure 120d. According to some example embodiments, in a plan view, the dummy vertical channel structure 120d may be arranged in the fourth portion 132d of the horizontal channel layer 132.

According to some example embodiments, the dummy vertical channel structure 120d and the fourth portion 132d of the horizontal channel layer 132 may have a concentric circular shape having a fourth center DCC. For example, in a plan view, a radius of the fourth portion 132d of the horizontal channel layer 132 may be greater than a radius of the dummy vertical channel structure 120d.

According to some example embodiments, the dummy vertical channel structure 120d may perform a function of mediating or isolating or separating the first vertical channel structure 120a and the second vertical channel structure 120b that are apart from each other in the horizontal direction (the X direction and/or the Y direction). According to some example embodiments, the fourth portion 132d of the horizontal channel layer 132 may be arranged between the first portion 132a and the second portion 132b and may mediate between the first portion 132a and the second portion 132b. For example, the horizontal channel layer 132 may include the fourth portion 132d, and thus, may have an increased planar area. For example, the horizontal channel layer 132 may extend between the first and second vertical channel structures 120a and 120b and may contact the first and second vertical channel structures 120a and 120b, and in a plan view, the fourth portion 132d of the horizontal channel layer 132 may perform a function of a bridge connecting between the first and second portions 132a and 132b.

The dummy vertical channel structure 120d may be arranged in a fourth channel hole CH4 arranged between the first channel hole CH1 and the second channel hole CH2 to be apart from the first channel hole CH1 and the second channel hole CH2 in the horizontal direction (the X direction and/or the Y direction) and passing through the interlayer insulating layer 105, the gate electrode layer 107, and the upper insulating layer 109 in the vertical direction (the Z direction). According to some example embodiments, the dummy vertical channel structure 120d may include a fourth gate dielectric layer 112d, a fourth channel area 114d, a fourth buried insulating layer 116d, and a fourth conductive plug 118d.

According to some example embodiments, the fourth gate dielectric layer 112d, the fourth channel area 114d, the fourth buried insulating layer 116d, and the fourth conductive plug 118d may respectively have substantially the same structure and include substantially the same material as the first gate dielectric layer 112a, the first channel area 114a, the first buried insulating layer 116a, and the first conductive plug 118a of the first vertical channel structure 120a described above. For example, the fourth gate dielectric layer 112d may include the blocking dielectric layer DL1, the charge storage layer DL2, and the tunneling dielectric layer DL3.

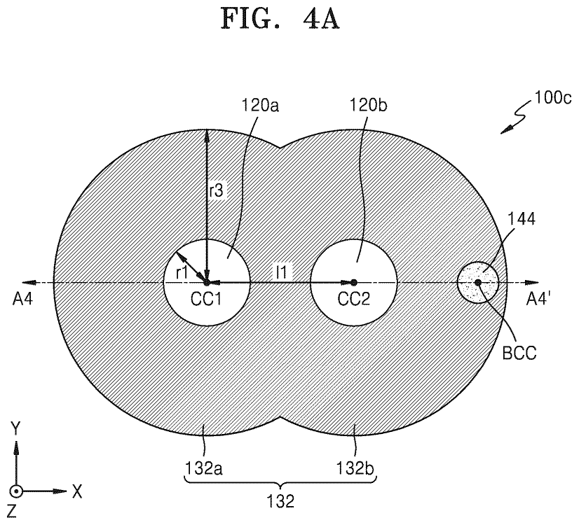

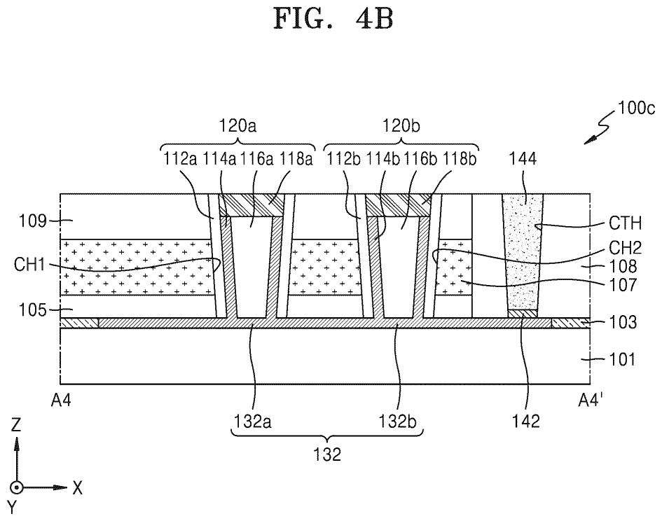

FIG. 4A is a plan view for describing a field effect transistor 100c according to some example embodiments. FIG. 4B is a cross-sectional view of the field effect transistor 100c taken along line A4-A4′ of FIG. 4A. A In FIGS. 4A and 4B, the field effect transistor 100c further includes a body contact 144 connected to the horizontal channel layer 132.

Referring to FIGS. 4A and 4B, the field effect transistor 100c may include the body contact 144 arranged apart from the first vertical channel structure 120a and the second vertical channel structure 120b in the horizontal direction (the X direction and/or the Y direction) and a conductive pad 142 between the body contact 144 and the horizontal channel layer 132. According to some example embodiments, the body contact 144 may be connected to the horizontal channel layer 132 through the conductive pad 142.

According to some example embodiments, the body contact 144 may be insulated from the gate electrode layer 107 by an insulating structure 108. According to some example embodiments, the insulating structure 108 may cover a portion of the horizontal channel layer 132 and a portion of the sacrificial insulating layer 103 and may include a portion facing the interlayer insulating layer 105, the gate electrode layer 107, and the upper insulating layer 109. According to some example embodiments, the insulating structure 108 may have, above the horizontal channel layer 132, a contact hole CTH apart from the first channel hole CH1 and the second channel hole CH2 in the horizontal direction and exposing the upper surface of the horizontal channel layer 132 by passing through the insulating structure 108 in the vertical direction (the Z direction). According to some example embodiments, the conductive pad 142 covering the upper surface of the horizontal channel layer 132 may be arranged in the contact hole CTH, and the body contact 144 may be arranged on the conductive pad 142 to fill a remaining portion of the contact hole CTH.

According to some example embodiments, the conductive pad 142 may have a conductivity type that is the opposite to a conductivity type of the first conductive plug 118a and the second conductive plug 118b. For example, the first conductive plug 118a and the second conductive plug 118b may include polysilicon doped with a dopant having a first conductivity type, and the conductive pad 142 may include polysilicon doped with a dopant having a second conductivity type that is the opposite to the first conductivity type. For example, the first and second conductive plugs 118a and 118b may include polysilicon doped with an n-type dopant, and the conductive pad 142 may include polysilicon doped with a p-type dopant. On the contrary, the first and second conductive plugs 118a and 118b may include polysilicon doped with a p-type dopant, and the conductive pad 142 may include polysilicon doped with an n-type dopant.

According to some example embodiments, the body contact 144 may include tungsten, titanium, tantalum, copper, aluminum, titanium nitride, tantalum nitride, tungsten nitride, or a combination thereof. According to some example embodiments, the insulating structure 108 may include silicon nitride, silicon oxide, or a combination thereof.

According to some example embodiments, in a plan view, the body contact 144 may be arranged in the horizontal channel layer 132. According to some example embodiments, the horizontal channel layer 132 may include the first portion 132a overlapping the first vertical channel structure 120a and the second portion 132b overlapping the second vertical channel structure 120b to have an increased planar area, and thus, the contact margin of the body contact 144 may be secured.

For example, the first portion 132a of the field effect transistor 100c illustrated in FIG. 4A may have a third radius r3 from the first center CC1, and the third radius r3 may be greater than the second radius r2 of the first portion 132a of the field effect transistor 100 illustrated in FIG. 1A. For example, the field effect transistor 100c may have a structure in which the radiuses of the first portion 132a and the second portion 132b are increased, and thus, the contact margin for connecting the body contact 144 to the horizontal channel layer 132 may be secured.

In FIG. 4A, it is illustrated that the first center CC1 of the first portion 132a, the second center CC2 of the second portion 132b, and a fifth center BCC of the body contact 144 are linearly arranged in the first horizontal direction (the X direction). However, the arrangement thereof is not limited thereto. For example, the body contact 144 may be apart from the first and second vertical channel structures 120a and 120b in the second horizontal direction (the Y direction), and in this case, a line connecting the first center CC1 of the first portion 132a, the second center CC2 of the second portion 132b, and the fifth center BCC of the body contact 144 may form a triangle.

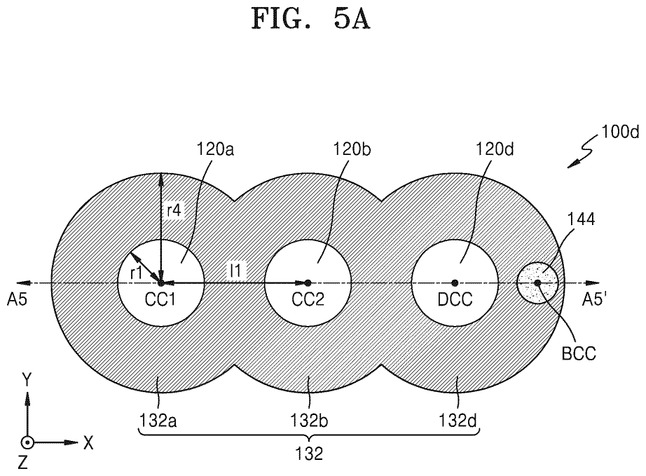

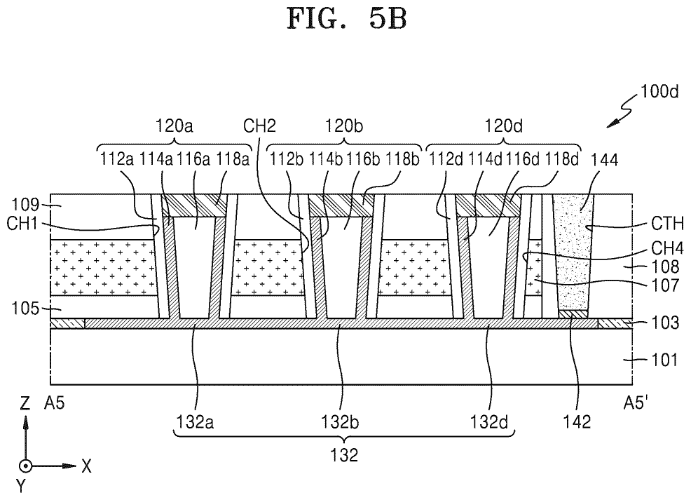

FIG. 5A is a plan view for describing a field effect transistor 100d according to some example embodiments. FIG. 5B is a cross-sectional view of the field effect transistor 100d taken along line A5-A5′ of FIG. 5A. In FIGS. 5A and 5B, the field effect transistor 100d further includes the dummy vertical channel structure 120d.

Referring to FIGS. 5A and 5B, the field effect transistor 100d may include the dummy vertical channel structure 120d, and the horizontal channel layer 132 may include the fourth portion 132d overlapping the dummy vertical channel structure 120d in the vertical direction (the Z direction). According to some example embodiments, the horizontal channel layer 132 may extend in a direction in which the first vertical channel structure 120a, the second vertical channel structure 120b, and the dummy vertical channel structure 120d are arranged and may have an extended structure. According to some example embodiments, the body contact 144 may be arranged in the horizontal channel layer 132, in a plan view.

According to some example embodiments, the field effect transistor 100d may include the dummy vertical channel structure 120d and the fourth portion 132d, and thus, while the horizontal channel layer 132 may be extended, spatial efficiency may be increased. As illustrated in FIG. 5A, the dummy vertical channel structure 120d may be linearly arranged along with the first vertical channel structure 120a and the second vertical channel structure 120b in the first horizontal direction (the X direction), and thus, the horizontal channel layer 132 may extend in the first horizontal direction (the X direction), and the fourth portion 132d of the horizontal channel layer 132 may perform a function of a pad for securing the contact margin of the body contact 144 in the first horizontal direction (the X direction).

FIG. 5A illustrates that the dummy vertical channel structure 120d is arranged between the first and second vertical channel structures 120a and 120b and the body contact 144. However, the arrangement of the dummy vertical channel structure 120d is not limited thereto. For example, the dummy vertical channel structure 120d may be arranged between the first vertical channel structure 120a and the second vertical channel structure 120b.

For example, the field effect transistor 100d may include the dummy vertical channel structure 120d, and thus, an unnecessary area (for example, an area of the horizontal channel layer 132 in the second horizontal direction in FIG. 4A) of the horizontal channel layer 132 may be reduced, to increase spatial efficiency.

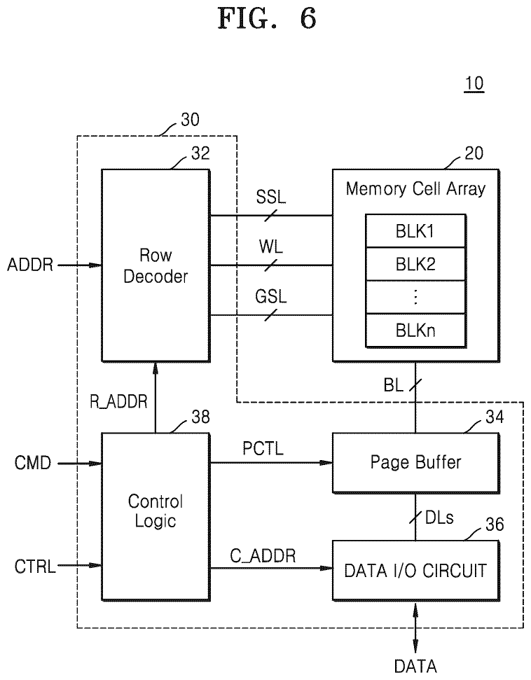

FIG. 6 is a block diagram of a semiconductor device 10 according to some example embodiments.

Referring to FIG. 6, the semiconductor device 10 may include a memory cell array 20 and a peripheral circuit 30. The memory cell array 20 may include a plurality of memory cell blocks BLK1, BLK2, . . . , and BLKn. Each of the plurality of memory cell blocks BLK1, BLK2, . . . , and BLKn may include a plurality of memory cells, e.g. arranged into sub-blocks (not shown). The memory cell blocks BLK1, BLK2, . . . , and BLKn may be connected to the peripheral circuit 30 through a column or bit line BL, a row or word line WL, a string selection line SSL, and a ground selection line GSL.

The peripheral circuit 30 may include a row decoder 32, a page buffer 34, a data input and output circuit 36, and a control logic 38. Although not illustrated in FIG. 6, the peripheral circuit 30 may further include one or more of an input and output interface, a column logic, a voltage generator, a pre-decoder, a temperature sensor, a command decoder, an address decoder, an amplification circuit, etc.

The memory cell array 20 may be connected to the page buffer 34 through the bit line BL and connected to the row decoder 32 through the word line WL, the string selection line SSL, and the ground selection line GSL. In the memory cell array 20, the plurality of memory cells included in the plurality of memory cell blocks BLK1, BLK2, . . . , and BLKn may be flash memory cells. The memory cell array 20 may include a three-dimensional memory cell array. The three-dimensional memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10 and may transmit and/or receive data DATA to and/or from a device outside the semiconductor device 10.

The row decoder 32 may select at least one of the plurality of memory cell blocks BLK1, BLK2, . . . , and BLKn in response to the address ADDR from the outside and may select the word line WL, the string selection line SSL, and the ground selection line GSL of the selected memory cell block. The row decoder 32 may transmit a voltage for performing a memory operation, to the word line WL of the selected memory cell block.

The page buffer 34 may be connected to the memory cell array 20 through the bit line BL. The page buffer 34 may operate, during a program operation, as a write driver and apply, to the bit line BL, a voltage according to data DATA to be stored in the memory cell array 20 and may operate, during a read operation, as a sense amplifier and sense the data DATA stored in the memory cell array 20. The page buffer 34 may operate according to a control signal PCTL provided from the control logic 38.

The data input and output circuit 36 may be connected to the page buffer 34 through data lines DLs. During a program operation, the data input and output circuit 36 may receive data DATA from a memory controller (not shown) and provide program data DATA to the page buffer 34 based on a column address C_ADDR provided from the control logic 38. During a read operation, the data input and output circuit 36 may provide, to the memory controller, read data DATA stored in the page buffer 34, based on the column address C_ADDR provided form the control logic 38.

The data input and output circuit 36 may transmit, to the control logic 38 or the row decoder 32, an input address or instruction. The peripheral circuit 30 may further include an electrostatic discharge (ESD) circuit and/or a pull-up/pull-down driver.

The control logic 38 may receive the command CMD and the control signal CTRL from the memory controller. The control logic 38 may provide a row address R_ADDR to the row decoder 32 and a column address C_ADDR to the data input and output circuit 36. The control logic 38 may generate, in response to the control signal CTRL, various internal control signals used in the semiconductor device 10. For example, the control logic 38 may adjust a voltage level provided to the word line WL and the bit line BL during a memory operation, such as a program operation or an erase operation.

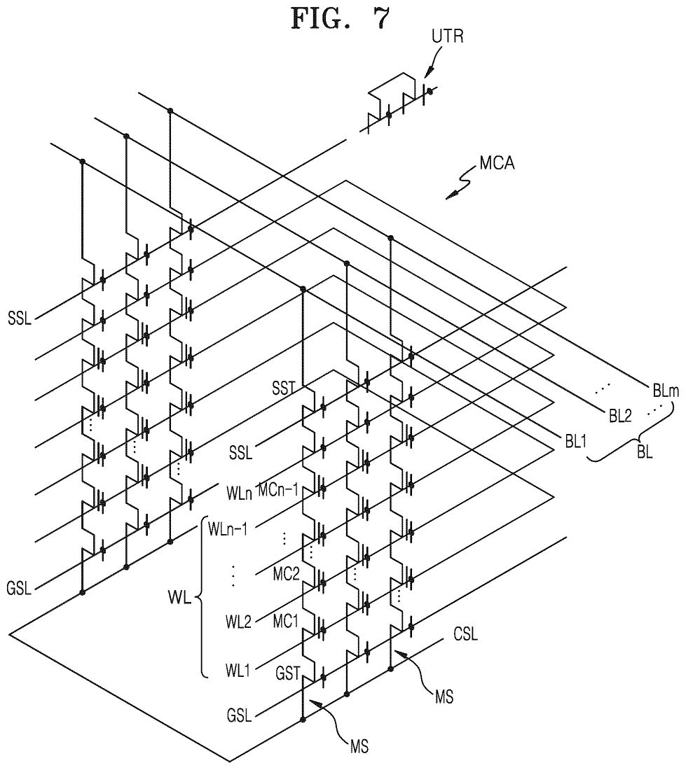

FIG. 7 is an equivalent circuit diagram of a memory cell array MCA of the semiconductor device 10 according to some example embodiments.

Referring to FIG. 7, the memory cell array MCA may include a plurality of memory cell strings MS. The memory cell array MCA may include a plurality of bit lines BL (BL1, BL2, . . . , and BLm), a plurality of word lines WL (WL1, WL2, . . . , WLn−1, and WLn), at least one string selection line SSL, at least one ground selection line GSL, and a common source line CSL. The plurality of memory cell strings MS may be formed between the plurality of bit lines BL (BL1, BL2, . . . , and BLm) and the common source line CSL. FIG. 7 illustrates an example in which the plurality of memory cell strings MS include one string selection line SSL. However, example embodiments are not limited thereto. For example, each of the plurality of memory cell strings MS may include two or more string selection lines SSL.

Each of the plurality of memory cell strings MS may include a string selection transistor SST, a ground selection transistor GST, and a plurality of memory cell transistors MC1, MC2, . . . MCn−1, and MCn. A drain area of the string selection transistor SST may be connected to the bit lines BL (BL1, BL2, . . . , and BLm), and a source area of the ground selection transistor GST may be connected to the common source line CSL. The common source line CSL may be or may correspond to an area to which source areas of a plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, . . . , MCn−1, and MCn may be connected to the plurality of word lines WL (WL1, WL2, . . . , WLn−1, and WLn), respectively.

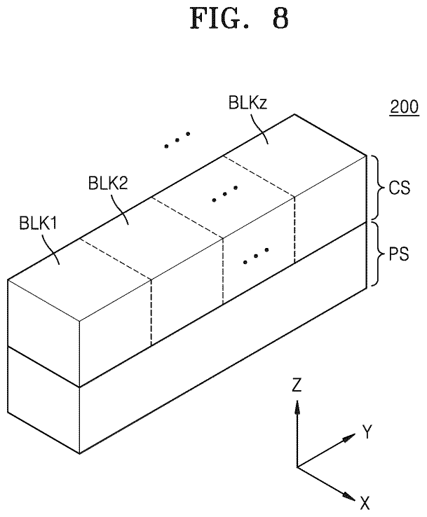

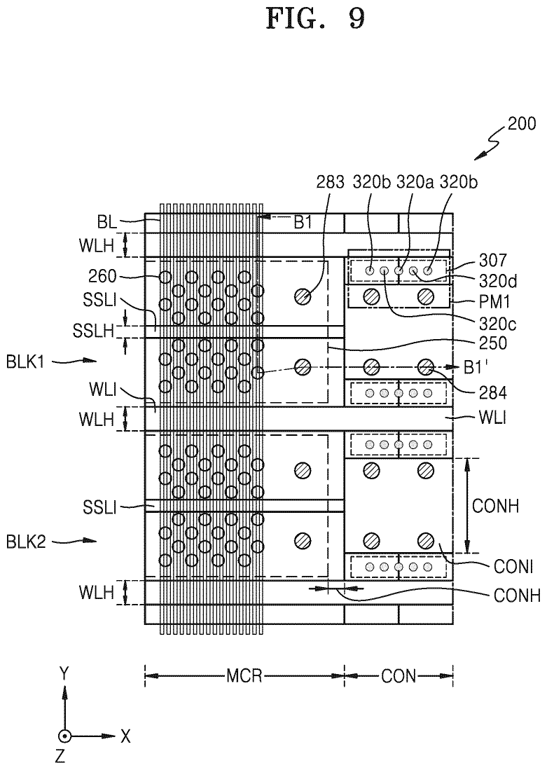

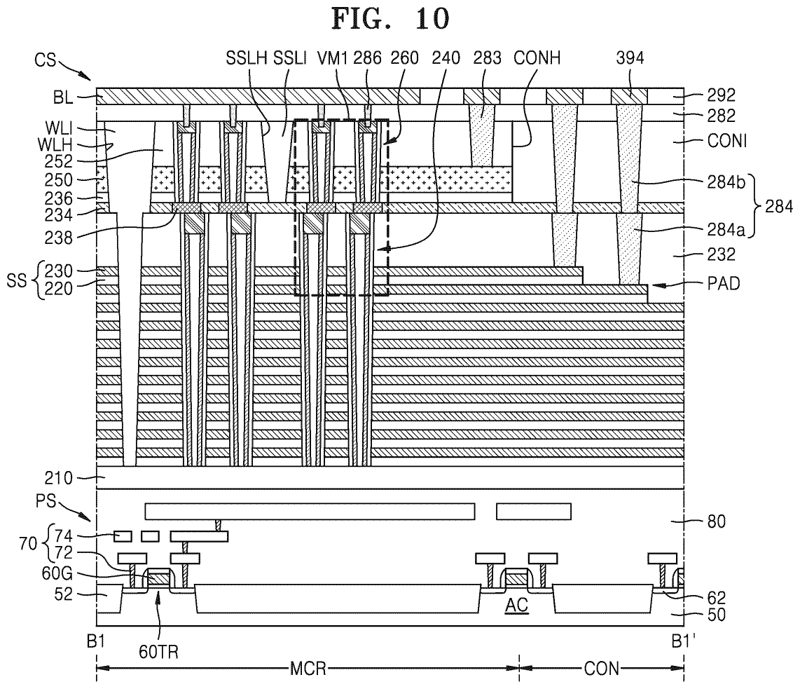

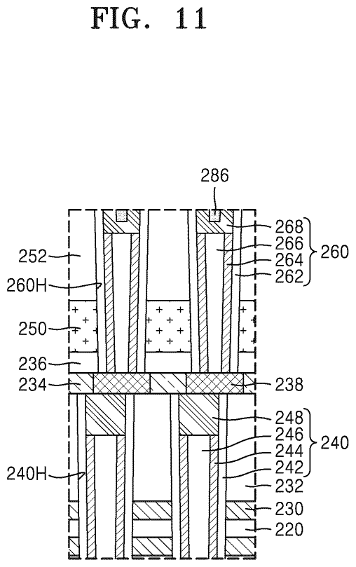

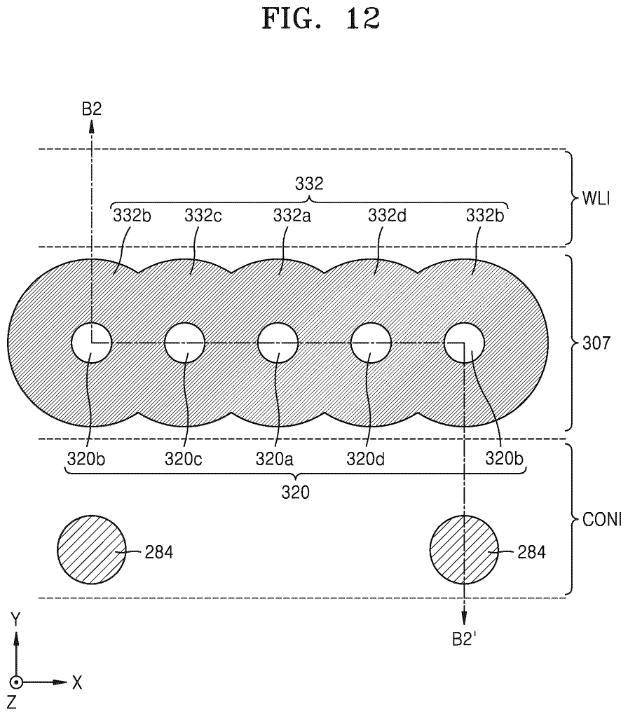

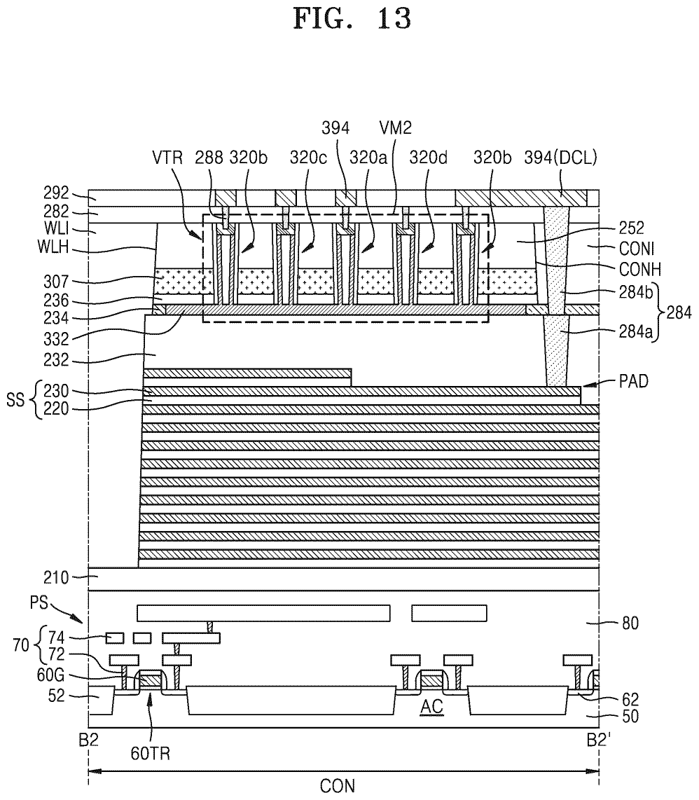

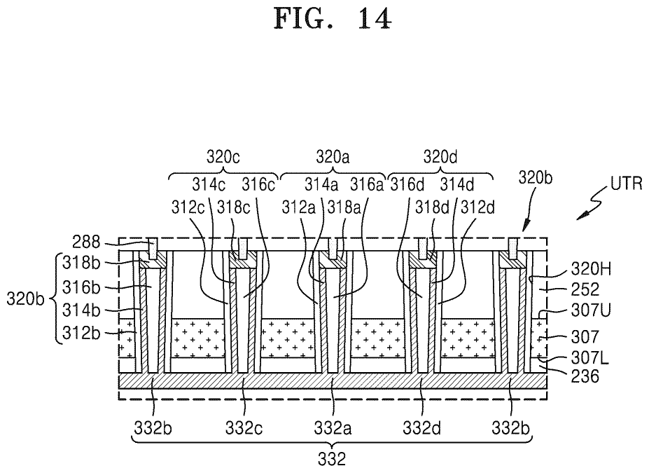

FIG. 8 is a perspective view showing representative components of a semiconductor device 200 according to some example embodiments. FIG. 9 is a plan view of the semiconductor device 200 according to some example embodiments. FIG. 10 is a cross-sectional view of the semiconductor device 200 taken alone line B1-B1′ of FIG. 9. FIG. 11 is an enlarged view of a region indicated as “VM1” in FIG. 10. FIG. 12 is an enlarged view of a region indicated as “PM1” in FIG. 9. FIG. 13 is a cross-sectional view of the semiconductor device 200 taken along line B2-B2′ of FIG. 12. FIG. 14 is an enlarged view of a region indicated as “VM2” in FIG. 13.

Referring to FIGS. 8 to 14, the semiconductor device 200 may include a cell array structure CS and a peripheral circuit structure PS overlapping each other in a vertical direction Z. For example, the semiconductor device 200 may have a cell over periphery or cell on periphery (COP) structure in which the cell array structure CS is arranged on the peripheral circuit structure PS.

The cell array structure CS may include the memory cell array 20 described with reference to FIG. 6, and the peripheral circuit structure PS may include the peripheral circuit 30 described with reference to FIG. 6. For example, the cell array structure CS may include a plurality of memory cell blocks BLK1, BLK2, . . . , and BLKn. Each of the plurality of memory cell blocks BLK1, BLK2, . . . , and BLKn may include three-dimensionally arranged memory cells.

According to some example embodiments, the peripheral circuit structure PS may include a peripheral circuit transistor 60TR and a peripheral circuit line structure 70 arranged on a semiconductor substrate 50. The semiconductor substrate 50 may include a memory cell region MCR and a connection region CON horizontally arranged. The memory cell region MCR may be an area in which the memory cell array MCA is formed, and the connection region CON may be an area in which a pad portion PAD is formed for electrical connection between the memory cell array MCA formed in the memory cell region MCR and a peripheral circuit region (not shown).

An active region AC may be defined on the semiconductor substrate 50 by a device isolation layer 52, and a plurality of peripheral circuit transistors 60TR may be formed on the active region AC. The plurality of peripheral circuit transistors 60TR may include a peripheral circuit gate 60G, and a source/drain area 62 arranged on a portion of the semiconductor substrate 50 at both sides of the peripheral circuit gate 60G.

According to some example embodiments, the semiconductor substrate 50 may include a semiconductor material, for example, a group IV-based semiconductor, a groups III-V-based compound semiconductor, or a groups II-IV-based oxide semiconductor. For example, the group IV-based semiconductor may include one or more of Si, Ge, or Si—Ge. The semiconductor substrate 50 may be provided as a bulk wafer or an epitaxial layer; however, example embodiments are not limited thereto, and the semiconductor substrate 50 may be singulated or diced. According to various example embodiments, the semiconductor substrate 50 may include a silicon-on-insulator (SOI) substrate or a germanium-on-insulator (GeOI) substrate.

According to some example embodiments, the peripheral circuit line structure 70 may include a plurality of peripheral circuit contacts 72 and a plurality of peripheral circuit line layers 74. An interlayer insulating layer 80 covering the peripheral circuit transistor 60TR and the peripheral circuit line structure 70 may be arranged on the semiconductor substrate 50. The plurality of peripheral circuit line layers 74 may have a multi-layered structure including a plurality of metal layers arranged at different vertical levels.

According to some example embodiments, a common source plate 210 may be arranged on the interlayer insulating layer 80. According to some example embodiments, the common source plate 210 may function as a source area for providing a current to vertical memory cells formed in the cell array structure CS. The common source plate 210 may be arranged in the memory cell region MCR and the connection region CON of the semiconductor substrate 50.

According to some example embodiments, the common source plate 210 may include at least one of Si, Ge, SiGe, GaAs, InGaAs, AlGaAs, or a compound thereof. The common source plate 210 may include a semiconductor doped with n-type impurities. The common source plate 210 may have a crystalline structure including at least one selected from monocrystalline, amorphous, and polycrystalline. According to some example embodiments, the common source plate 210 may include polysilicon doped with impurities such as n-type impurities.

According to some example embodiments, a gate stack SS may be arranged on the common source plate 210 in the memory cell region MCR and the connection region CON.

According to some example embodiments, the gate stack SS may include a plurality of mold insulating layers 220 and a plurality of first gate electrodes 230 alternately stacked in the vertical direction Z. According to some example embodiments, the gate stack SS may be covered by an insulating block 232, and a sacrificial insulating layer 234 may be arranged on the insulating block 232.

According to some example embodiments, the first gate electrodes 230 may include metal, such as tungsten, metal silicide, such as tungsten silicide, doped polysilicon, or a combination thereof. Although not shown, an upper surface, a bottom surface, and a side surface of the plurality of first gate electrodes 230 may be covered by a high dielectric material, such as aluminum oxide.

According to some example embodiments, the plurality of first gate electrodes 230 may correspond to the ground selection line GSL and the word lines WL (WL1, WL2, . . . , WLn−1, and WLn) included in the memory cell string MS (see FIG. 7). For example, a lowermost first gate electrode 230 may function as the ground selection line GSL, and the other first gate electrodes 230 may function as the word lines WL.

As illustrated in FIG. 9, a plurality of gate stack isolation holes WLH may extend in a first horizontal direction (an X direction) parallel with an upper surface of the common source plate 210, above the common source plate 210. The plurality of first gate electrodes 230 arranged between a pair of gate stack isolation holes WLH may form one block. For example, FIG. 9 illustrates a first block BLK1 and a second block BLK2.

According to some example embodiments, a gate stack isolation insulating layer WL1 filling an inner space of the gate stack isolation holes WLH may be arranged on the common source plate 210. The gate stack isolation insulating layer WL1 may include a silicon oxide layer, a silicon nitride layer, SiON, SiOCN, SiCN, or a combination thereof.

According to some example embodiments, a plurality of first channel structures 240 may extend in the vertical direction (the Z direction) by passing through the plurality of first gate electrodes 230 and the plurality of mold insulating layers 220 from the upper surface of the common source plate 210, in the memory cell region MCR. The plurality of first channel structures 240 may be arranged apart from each other by a predetermined distance in the horizontal direction (the X direction and/or a Y direction). In a plan view, the plurality of first channel structures 240 may be arranged to have a zigzag shape or a staggered shape.

According to some example embodiments, each of the plurality of first channel structures 240 may be arranged in a first channel hole 240H in the memory cell region MCR. Each of the plurality of first channel structures 240 may include a first gate insulating layer 242, a first channel layer 244, a first buried insulating layer 246, and a first conductive plug 248. The first gate insulating layer 242 and the first channel layer 244 may be sequentially arranged on a side wall of the first channel hole 240H. For example, the first gate insulating layer 242 may be conformally arranged on the side wall of the first channel hole 240H, and the first channel layer 244 may be conformally arranged on a side wall of the first gate insulating layer 242. The first buried insulating layer 246 filling a remaining space of the first channel hole 240H may be arranged on the first channel layer 244. The first conductive plug 248 contacting the first channel layer 244 and blocking an entrance to the first channel hole 240H may be arranged above the first channel hole 240H.

According to some example embodiments, the plurality of first channel structures 240 may be arranged in contact with the upper surface of the common source plate 210 at a bottom portion of the first channel hole 240H. According to some example embodiments, a contact semiconductor layer (not shown) having a predetermined height may be formed on the common source plate 210 at the bottom portion of the first channel hole 240H, and the first channel layer 244 may be electrically connected to the common source plate 210 through the contact semiconductor layer.

According to some example embodiments, the sacrificial insulating layer 234 may be arranged on the insulating block 232. According to some example embodiments, a horizontal channel layer 332 may be arranged on the insulating block 232 in the connection region CON and may be insulated by the sacrificial insulating layer 234. For example, the sacrificial insulating layer 234 and the horizontal channel layer 332 may have the same vertical level as each other, and in a plan view, the horizontal channel layer 332 may be surrounded by the sacrificial insulating layer 234. According to some example embodiments, the sacrificial insulating layer 234 and the horizontal channel layer 332 may be covered by the interlayer insulating layer 236.

According to some example embodiments, in the memory cell region MCR, a second gate electrode 250 may be arranged on the interlayer insulating layer 236, and in the connection region CON, a plurality of upper gate layers 307 may be arranged on the interlayer insulating layer 236. According to some example embodiments, each of the second gate electrode 250 and the plurality of upper gate layers 307 may be covered by an upper insulating layer 252. According to some example embodiments, the second gate electrode 250 and the plurality of upper gate layers 307 may be arranged at the same vertical level as each other.

According to some example embodiments, the second gate electrode 250 and the plurality of upper gate layers 307 may be apart from each other in the first horizontal direction (the X direction) due to an upper isolation hole CONH. In one memory cell block (for example, the memory cell block BLK1), the plurality of upper gate layers 307 may be apart from each other in a second horizontal direction (the Y direction) due to the upper isolation hole CONH. According to some example embodiments, an upper insulating structure CONI may be arranged in the upper isolation hole CONH.

According to some example embodiments, the upper insulating structure CONI may include a first horizontal extension portion extending in the first horizontal direction (the X direction) and a second horizontal extension portion extending in the second horizontal direction (the Y direction). For example, the second gate electrode 250 and the plurality of upper gate layers 307 may be apart from each other in the first horizontal direction (the X direction) with the second horizontal extension portion of the upper insulating structure CONI therebetween. For example, two upper gate layers 307 may be arranged in one memory cell block (for example, the first block BLK1), and the first horizontal extension portion of the upper insulating structure COIN may be arranged between the two upper gate layers 307. As illustrated in FIG. 9, the plurality of upper gate layers 307 may be arranged in parallel with each other in the second horizontal direction (the Y direction) due to the gate stack isolation insulating layer WL1 and the upper insulating structure CONI.

According to some example embodiments, the second gate electrode 250 and the plurality of upper gate layers 307 may be electrically insulated from each other due to the upper insulating structure CONI. According to some example embodiments, the upper gate layers 307 may be formed by the same process as the second gate electrode 250, and accordingly, the manufacturing yield rate of the semiconductor device 200 may be improved.

According to some example embodiments, the second gate electrode 250 and the upper gate layers 307 may be formed as a single-layered structure including polysilicon, a stack structure including oxide/polysilicon, or a stack structure including oxide/metal, but are not limited thereto. Although not shown, an upper surface, a bottom surface, and a side surface of each of the second gate electrode 250 and the upper gate layers 307 may be covered by a high dielectric material, such as but not limited to aluminum oxide. According to some example embodiments, the second gate electrode 250 may correspond to the string selection line SSL described with reference to FIG. 7. In this specification, the second gate electrode 250 may be referred to as a string selection line gate layer.

According to some example embodiments, a plurality of second channel structures 260 may penetrate the interlayer insulating layer 236, the second gate electrode 250, and the upper insulating layer 252 and extend in the vertical direction (the Z direction) in the memory cell region MCR. According to some example embodiments, the plurality of second channel structures 260 may be arranged apart from each other by a predetermined distance in the horizontal direction (the X direction and/or the Y direction). For example, the plurality of second channel structures 260 may be arranged to have a zigzag shape or a staggered shape. According to some example embodiments, the plurality of second channel structures 260 may be electrically connected to the plurality of first channel structures 240 through a plurality of conductive vias 238.

According to some example embodiments, each of the plurality of second channel structures 260 may be arranged in a second channel hole 260H in the memory cell region MCR. Each of the plurality of second channel structures 260 may include a second gate insulating layer 262, a second channel layer 264, a second buried insulating layer 266, and a second conductive plug 268. The second gate insulating layer 262 and the second channel layer 264 may be sequentially arranged on a side wall of the second channel hole 260H. For example, the second gate insulating layer 262 may be conformally arranged on the side wall of the second channel hole 260H, and the second channel layer 264 may be conformally arranged on a side wall of the second gate insulating layer 262. The second buried insulating layer 266 filling a remaining space of the second channel hole 260H may be arranged on the second channel layer 264. The second conductive plug 268 contacting the second channel layer 264 and blocking an entrance to the second channel hole 260H may be arranged above the second channel hole 260H.

According to some example embodiments, the second gate electrode 250 may be separated into two planar portions by a string isolation hole SSLH in one block. According to some example embodiments, a string isolation insulating layer SSLI may be arranged in the string isolation hole SSLH, and the two portions of the second gate electrode 250 may be apart from each other in the second horizontal direction (the Y direction) with the string isolation insulating layer SSLI therebetween. The two portions of the second gate electrode 250 may form the string selection line SSL described with reference to FIG. 7.

According to some example embodiments, the plurality of vertical channel structures 320 may penetrate the interlayer insulating layer 236, the upper gate layers 307, and the upper insulating layer 252 and extend in the vertical direction (the Z direction) in the connection region CON. According to some example embodiments, the plurality of vertical channel structures 320 may be connected to the horizontal channel layer 332. According to some example embodiments, the plurality of vertical channel structures 320, the upper gate layers 307, and the horizontal channel layer 332 may form an upper transistor UTR, and the upper transistor UTR may have substantially the same structure as the field effect transistors 100 to 100d described with reference to FIGS. 1A to 5B.

According to some example embodiments, the horizontal channel layer 332 may overlap the plurality of vertical channel structures 320 in the vertical direction (the Z direction). According to some example embodiments, the horizontal channel layer 332 may have a greater planar area than the plurality of vertical channel structures 320. According to some example embodiments, in a planar perspective, the plurality of vertical channel structures 320 may be arranged in the horizontal channel layer 332. According to some example embodiments, the horizontal channel layer 332 may extend in a direction in which the plurality of vertical channel structures 320 are arranged. FIGS. 9 and 12 illustrate that the plurality of vertical channel structures 320 are arranged in the first horizontal direction (the X direction), and the horizontal channel layer 332 extends in the first horizontal direction (the X direction). However, the plurality of vertical channel structures 320 and the horizontal channel layer 332 are not limited thereto.

According to some example embodiments, the plurality of vertical channel structures 320 may include a source channel structure 320a, a drain channel structure 320b, a body channel structure 320c, and a dummy vertical channel structure 320d. According to some example embodiments, the horizontal channel layer 332 may include a source horizontal channel layer 332a connected to a source channel structure 320a, a drain horizontal channel layer 332b connected to a drain channel structure 320b, a body horizontal channel layer 332c connected to a body channel structure 320c, and a dummy horizontal channel layer 332d connected to a dummy vertical channel structure 320d.

According to some example embodiments, the source horizontal channel layer 332a, the drain horizontal channel layer 332b, the body horizontal channel layer 332c, and the dummy horizontal channel layer 332d may integrally form the horizontal channel layer 332. According to some example embodiments, each of the source horizontal channel layer 332a, the drain horizontal channel layer 332b, the body horizontal channel layer 332c, and the dummy horizontal channel layer 332d may have a circular planar shape, and the horizontal channel layer 332 may have a planar shape in which a plurality of circles kiss or partially overlap each other or form a figure-eight shape or double-donut shape.

According to some example embodiments, the source channel structure 320a may be arranged in an upper channel hole 320H passing through the interlayer insulating layer 236, the upper gate layers 307, and the upper insulating layer 252 in the vertical direction (the Z direction). According to some example embodiments, the source channel structure 320a may include a gate insulating layer 312a, a channel layer 314a, a buried insulating layer 316a, and a conductive plug 318a. According to some example embodiments, the gate insulating layer 312a and the channel layer 314a may be sequentially arranged on a side wall of the upper channel hole 320H. For example, the gate insulating layer 312a may be conformally arranged on the side wall of the upper channel hole 320H, and the channel layer 314a may be conformally arranged on a side wall of the gate insulating layer 312a. The buried insulating layer 316a filling a remaining space of the upper channel hole 320H may be arranged on the channel layer 314a. The conductive plug 318a contacting the channel layer 314a and blocking an entrance to the upper channel hole 320H may be arranged above the upper channel hole 320H.

According to some example embodiments, the drain channel structure 320b may have substantially the same structure as the source channel structure 320a. According to some example embodiments, the drain channel structure 320b may include a gate insulating layer 312b, a channel layer 314b, a buried insulating layer 316b, and a conductive plug 318b.

According to some example embodiments, the body channel structure 320c may have substantially the same structure as the source channel structure 320a. According to some example embodiments, the body channel structure 320c may include a gate insulating layer 312c, a channel layer 314c, a buried insulating layer 316c, and a conductive plug 318c.

According to some example embodiments, the dummy vertical channel structure 320d may have substantially the same structure as the source channel structure 320a. According to some example embodiments, the dummy vertical channel structure 320d may include a gate insulating layer 312d, a channel layer 314d, a buried insulating layer 316d, and a conductive plug 318d.

According to some example embodiments, the upper gate layers 307 may have a first surface 307L and a second surface 307U that are opposite to each other. According to some example embodiments, a lower end of each of the channel layers 314a, 314b, 314c, and 314d of the plurality of vertical channel structures 320 may contact the horizontal channel layer 332 on the first surface 307L of the upper gate layers 307, and an upper end of each of the channel layers 314a, 314b, 314c, and 314d of the plurality of vertical channel structures 320 may contact each of the conductive plugs 318a, 318b, 318c, and 318d of the plurality of vertical channel structures 320 on the second surface 307U of the upper gate layers 307. Accordingly, the wire complexity may be alleviated or improved upon, and the spatial efficiency of the semiconductor device may be increased.

According to some example embodiments, the conductive plug 318c of the body channel structure 320c may have a different conductivity type from the conductive plug 318a of the source channel structure 320a and the conductive plug 318b of the drain channel structure 320b. For example, the conductive plug 318c of the body channel structure 320c may include polysilicon doped with a dopant having a first conductivity type, and the conductive plug 318a of the source channel structure 320a and the conductive plug 318b of the drain channel structure 320b may include polysilicon doped with a dopant having a second conductivity type that is the opposite to the first conductivity type.

According to some example embodiments, the dummy horizontal channel layer 332d may mediate the plurality of vertical channel structures 320 adjacent to the dummy vertical channel structure 320d. For example, the dummy horizontal channel layer 332d may mediate the source channel structure 320a and the drain channel structure 320b adjacent to the dummy vertical channel structure 320d. In this case, the dummy horizontal channel layer 332d may perform a function of a bridge connecting between the source channel structure 320a and the drain channel structure 320b.

According to some example embodiments, a first insulating layer 282 may be arranged on the plurality of second channel structures 260 and the plurality of vertical channel structures 320. According to some example embodiments, the first insulating layer 282 may cover the plurality of second channel structures 260, the plurality of vertical channel structures 320, the upper insulating layer 252, the gate stack isolation insulating layer WL1, and the upper insulating structure CONI. According to some example embodiments, a plurality of first upper contacts 286 passing through the first insulating layer 282 and connected to the second conductive plug 268 of the plurality of second channel structures 260 may be arranged on the plurality of second channel structures 260. According to some example embodiments, a plurality of second upper contacts 288 passing through the first insulating layer 282 and connected to the conductive plugs 318a, 318b, 318c, and 318d of the plurality of vertical channel structures 320 may be arranged on the plurality of vertical channel structures 320. According to some example embodiments, the plurality of first upper contacts 286 and the plurality of second upper contacts 288 may be insulated from each other by the first insulating layer 282.

According to some example embodiments, an end of the plurality of first gate electrodes 230 and an end of the second gate electrode 250 may form a pad portion PAD. The plurality of first gate electrodes 230 and the second gate electrode 250 may extend to have a decreased length in the first horizontal direction (the X direction) as the plurality of first gate electrodes 230 and the second gate electrode 250 are distanced father apart from an upper surface of the common source plate 210. The pad portion PAD may refer to portions of the first gate electrodes 230 and an end of the second gate electrode 250, the portions and the end being arranged as a stair shape. According to some example embodiments, the portions of the plurality of first gate electrodes 230 forming the pad portion PAD may be covered by the insulating block 232, and the end of the second gate electrode 250 may be covered by the upper insulating layer 252.

According to some example embodiments, in the connection region CON, a plurality of first contact plugs 284 passing through the insulating block 232, the sacrificial insulating layer 234, the upper insulating structure CONI, and the first insulating layer 282 in the vertical direction and connected to the pad portion PAD of the plurality of first gate electrodes 230 may be arranged. For example, the plurality of first contact plugs 284 may include a first portion 284a passing through the insulating block 232 and a second portion 284b passing through the sacrificial insulating layer 234, the upper insulating structure CONI, and the first insulating layer 282. According to some example embodiments, in the memory cell region MCR, a second contact plug 283 passing through the upper insulating layer 252 and the first insulating layer 282 and connected to the pad portion PAD of the second gate electrode 250 may be arranged.

According to some example embodiments, a second insulating layer 292 covering the plurality of first upper contacts 286, the plurality of second upper contacts 288, the plurality of first contact plugs 284, and the second contact plug 283 may be arranged on the first insulating layer 282.

According to some example embodiments, in the memory cell region MCR, the plurality of bit lines BL may be connected to the plurality of first upper contacts 286 and may be insulated from each other by the second insulating layer 292. For example, the plurality of second channel structures 260 may be connected to the plurality of bit lines BL through the plurality of first upper contacts 286.

According to some example embodiments, an upper line 394 may extend on the first insulating layer 282 in the horizontal direction (the X direction and/or the Y direction), may be connected to the plurality of first contact plugs 284 in the connection region CON and the second contact plug 283 in the memory cell region MCR, and may be insulated by the second insulating layer 292.

According to some example embodiments, the upper line 394 may include a portion connected to some of the plurality of vertical channel structures 320. For example, a portion of the upper line 394 may form a source line connected to the source channel structure 320a and configured to apply a power/ground voltage to the upper transistor UTR. For example, a portion of the upper line 394 may be connected to the body channel structure 320c and configured to alleviate the body effect of the upper transistor UTR. According to some example embodiments, a portion DCL of the upper line 394 may electrically connect one selected from among the plurality of first contact plugs 284 with the drain vertical channel structure 320d.

The upper transistor UTR according to some example embodiments may be a portion of a peripheral circuit structure of a semiconductor device and a semiconductor element of a peripheral circuit region according to the related art. In the semiconductor device 200 according to some example embodiments, the upper transistor UTR may be arranged in the connection region CON by using a space on the gate stack SS, and thus, a size of the semiconductor device 200 may be reduced.

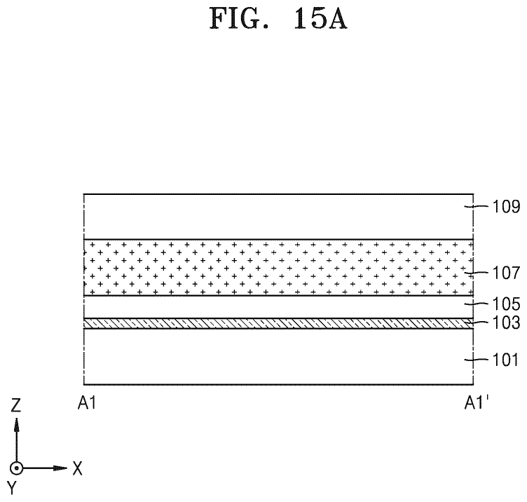

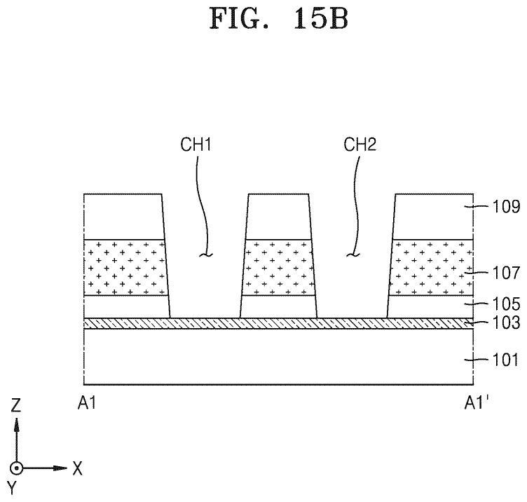

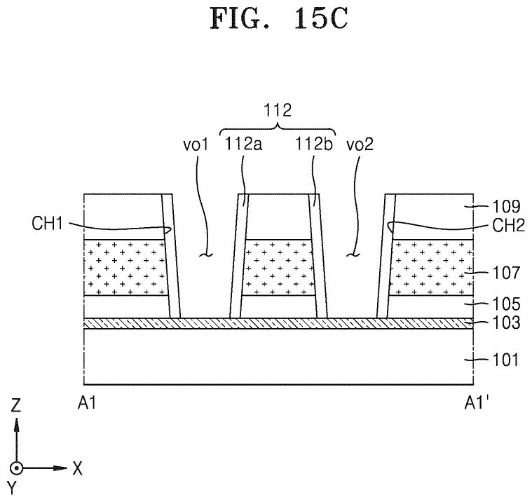

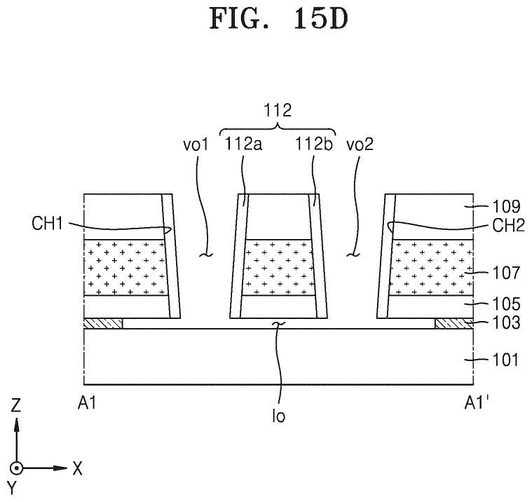

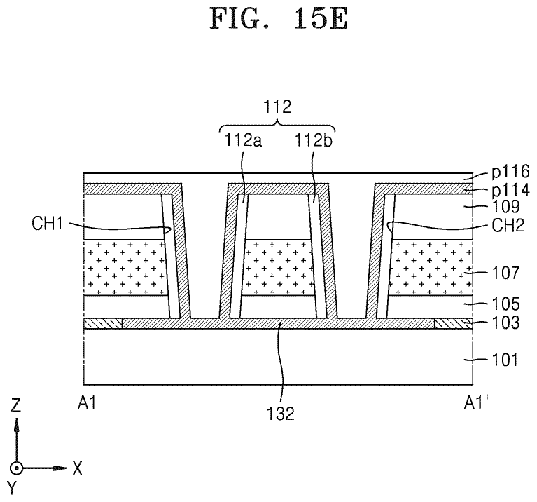

FIGS. 15A to 15E are cross-sectional views for describing a method of manufacturing the field effect transistor 100, according to some example embodiments. In detail, FIGS. 15A to 15E are cross-sectional views according to a process order of a portion corresponding to FIG. 1B. In FIGS. 15A to 15E, reference numerals the same as the reference numerals of FIGS. 1A to 1D refer to the same members, and their detailed descriptions are omitted herein.

Referring to FIG. 15A, the sacrificial insulating layer 103, the interlayer insulating layer 105, the gate electrode layer 107, and the upper insulating layer 109 may be sequentially stacked on the lower insulating layer 101 in a vertical direction (a Z direction), e.g., may be deposited with a process such as an atomic layer deposition (ALD) process.

Referring to FIG. 15B, a portion of a manufactured structure of FIG. 15A may be etched, e.g., dry etched, to form the first channel hole CH1 and the second channel hole CH2 passing through the interlayer insulating layer 105, the gate electrode layer 107, and the upper insulating layer 109 in the vertical direction (the Z direction). An upper surface of the sacrificial insulating layer 103 may be exposed by the first channel hole CH1 and the second channel hole CH2.

Referring to FIG. 15C, in a manufactured structure of FIG. 15B, a preliminary gate dielectric layer (not shown) conformally covering exposed inner walls and bottom surfaces of the first and second channel holes CH1 and CH2 may be formed, e.g. may be deposited with a process such as a chemical vapor deposition (CVD) process. Thereafter, a pattern mask (not shown) may be arranged, and a portion of the preliminary gate dielectric layer may be removed by a etch process to expose an upper surface of the sacrificial insulating layer 103 and form the first gate dielectric layer 112a and the second gate dielectric layer 112b. For example, a first opening vo1 defined by the first gate dielectric layer 112a and the exposed upper surface of the sacrificial insulating layer 103 may be formed, and a second opening vo2 defined by the second gate dielectric layer 112b and the exposed upper surface of the sacrificial insulating layer 103 may be formed, e.g., at the same time as the first opening vo1 is formed.

Referring to FIG. 15D, in a manufactured structure of FIG. 15C, a portion of the exposed sacrificial insulating layer 103 may be removed through the first opening vo1 and the second opening vo2 to form a lower opening lo. For example, the sacrificial insulating layer 103 may be removed by a wet etch process. For example, the sacrificial insulating layer 103 may be isotropically etched, e.g., with a wet etching, in a plan view.

Referring to FIG. 15E, in a manufactured structure of FIG. 15D, a preliminary channel layer p114 covering a surface exposed by the first opening vo1, the second opening vo2, and the lower opening lo may be formed. For example, the preliminary channel layer p114 may completely fill the lower opening lo, may conformally cover inner walls of the first and second gate dielectric layers 112a and 112b, may fill portions of the first opening vo1 and the second opening vo2, and may cover or conformally cover an upper surface of the upper insulating layer 109.

Thereafter, a preliminary buried insulating layer p116 filling remaining portions of the first opening vo1 and the second opening vo2 may be formed on the preliminary channel layer p114. For example, the preliminary buried insulating layer p116 may cover the preliminary channel layer p114 on the upper insulating layer 109.

Referring to FIGS. 15E and 1B together, in a manufactured structure of FIG. 15E, portions of the preliminary buried insulating layer p116 and the preliminary channel layer p114 may be removed through a planarization process to expose the first and second gate dielectric layers 112a and 112b and the upper insulating layer 109 below the preliminary buried insulating layer p116 and the preliminary channel layer p114. Thereafter, upper portions of the preliminary buried insulating layer p116 and the preliminary channel layer p114 may be removed to form the first and second buried insulating layers 116a and 116b and the first and second channel areas 114a and 114b defining an upper opening (not shown), and then, the first and second conductive plugs 118a and 118b filling the upper opening may be formed.

While various example embodiments have been particularly shown and described with reference to example embodiments thereof, it will be understood that various changes in form and details may be made therein without departing from the spirit and scope of the following claims. Furthermore example embodiments are not necessarily mutually exclusive with one another. For example, some example embodiments may include one or more features described with reference to one or more figures, and may also include one or more other features described with reference to one or more other figures.

What is claimed is:

1. A field effect transistor comprising:
a horizontal channel layer;
an interlayer insulating layer on the horizontal channel layer;
a gate electrode layer on the interlayer insulating layer;
a first vertical channel structure passing through the gate electrode layer and the interlayer insulating layer in a vertical direction, in contact with the horizontal channel layer, and connected to one of a source terminal or a drain terminal; and
a second vertical channel structure apart from the first vertical channel structure in a horizontal direction, passing through the gate electrode layer and the interlayer insulating layer in the vertical direction, in contact with the horizontal channel layer, and connected to another of the source terminal or the drain terminal.

2. The field effect transistor of claim 1, wherein the horizontal channel layer includes:
a first portion at least partially overlapping the first vertical channel structure in the vertical direction; and
a second portion at least partially overlapping the second vertical channel structure in the vertical direction,
wherein, in a plan view, the first portion has a greater planar area than a lower surface of the first vertical channel structure, and the second portion has a greater planar area than a lower surface of the second vertical channel structure.

3. The field effect transistor of claim 1, wherein the horizontal channel layer includes:
a first portion at least partially overlapping the first vertical channel structure in the vertical direction; and
a second portion at least partially overlapping the second vertical channel structure in the vertical direction,
wherein each of the first portion and the second portion has a circular planar shape, and
in a plan view, the horizontal channel layer has a planar shape in which a circle of the first portion and a circle of the second portion at least partially overlap each other.

4. The field effect transistor of claim 1, wherein the horizontal channel layer includes:
a first portion at least partially overlapping the first vertical channel structure in the vertical direction; and
a second portion at least partially overlapping the second vertical channel structure in the vertical direction,
wherein in a plan view, the first vertical channel structure and the first portion have a concentric circular shape, and the second vertical channel structure and the second portion have a concentric circular shape.

5. The field effect transistor of claim 1, further comprising:
a third vertical channel structure apart from the first vertical channel structure and the second vertical channel structure in the horizontal direction, passing through the gate electrode layer and the interlayer insulating layer in the vertical direction, and in contact with the horizontal channel layer.

6. The field effect transistor of claim 5, wherein
the first vertical channel structure includes a first vertical channel layer contacting the horizontal channel layer, and a first conductive plug on the first vertical channel layer,
the second vertical channel structure includes a second vertical channel layer contacting the horizontal channel layer, and a second conductive plug on the second vertical channel layer,
the third vertical channel structure includes, a third vertical channel layer contacting the horizontal channel layer, and a third conductive plug on the third vertical channel layer, and
the first conductive plug, the second conductive plug, and the third conductive plug include dopants having a same conductivity type.

7. The field effect transistor of claim 5, wherein
the first vertical channel structure includes a first vertical channel layer contacting the horizontal channel layer, and a first conductive plug on the first vertical channel layer,
the second vertical channel structure includes a second vertical channel layer contacting the horizontal channel layer, and a second conductive plug on the second vertical channel layer,
the third vertical channel structure includes, a third vertical channel layer contacting the horizontal channel layer, and a third conductive plug on the third vertical channel layer, and
each of the first conductive plug and the second conductive plug includes a dopant having a first conductivity type, and the third conductive plug includes a dopant having a second conductivity type which is opposite to the first conductivity type.

8. The field effect transistor of claim 1, further comprising:
a dummy vertical channel structure between the first vertical channel structure and the second vertical channel structure to be apart from the first vertical channel structure and the second vertical channel structure in the horizontal direction and passing through the gate electrode layer and the interlayer insulating layer in the vertical direction to be in contact with the horizontal channel layer.

9. The field effect transistor of claim 8, wherein the horizontal channel layer includes:
a first portion overlapping the first vertical channel structure in the vertical direction;
a second portion overlapping the second vertical channel structure in the vertical direction; and
a fourth portion overlapping the dummy vertical channel structure in the vertical direction,
wherein the fourth portion is between the first portion and the second portion.

10. The field effect transistor of claim 1, further comprising:
an insulating structure on the horizontal channel layer and facing the gate electrode layer in the horizontal direction; and
a body contact passing through the insulating structure and contacting the horizontal channel layer.

11. A semiconductor device comprising:
a semiconductor substrate having a memory cell region and a connection region;
a gate stack including a plurality of word line gate layers and a plurality of insulating layers, which extend in a horizontal direction and are alternately stacked in a vertical direction on a main surface of the semiconductor substrate, the gate stack having a stair structure including a plurality of pad portions in the connection region;
an insulating block on the gate stack;
a horizontal channel layer arranged on the insulating block in the connection region;
an interlayer insulating layer arranged on the horizontal channel layer;
a plurality of upper gate layers in the connection region, extending in a first horizontal direction on the interlayer insulating layer and arranged in parallel with each other in a second horizontal direction crossing the first horizontal direction; and
a plurality of vertical channel structures passing through the interlayer insulating layer and the plurality of upper gate layers and contacting the horizontal channel layer.

12. The semiconductor device of claim 11, further comprising:
a string selection line gate layer in the memory cell region and on the insulating block,
wherein the string selection line gate layer is arranged at a same vertical level as the plurality of upper gate layers.

13. The semiconductor device of claim 11, further comprising:
an insulating structure on the insulating block and between the plurality of upper gate layers; and
a plurality of contact structures in the connection region, passing through the insulating block and the insulating structure in the vertical direction, and connected to the plurality of pad portions.

14. The semiconductor device of claim 13, wherein a first vertical channel structure selected from among the plurality of vertical channel structures is connected to a first contact structure selected from among the plurality of contact structures.

15. The semiconductor device of claim 11, wherein
the horizontal channel layer at least partially overlaps the plurality of vertical channel structures in the vertical direction and
has a greater planar area than the plurality of vertical channel structures.

16. The semiconductor device of claim 11, wherein the horizontal channel layer extends in a direction in which the plurality of vertical channel structures are arranged.

17. The semiconductor device of claim 11, wherein
the horizontal channel layer includes a plurality of sub-horizontal channel layers respectively at least partially overlapping the plurality of vertical channel structures in the vertical direction,
each of the plurality of sub-horizontal channel layers has a circular planar shape, and
the horizontal channel layer has a planar shape in which a plurality of circles of the plurality of sub-horizontal channel layers at least partially overlap each other.

18. The semiconductor device of claim 11, wherein
the plurality of vertical channel structures include a first vertical channel structure, a second vertical channel structure, and a third vertical channel structure, the second and third vertical channel structures being apart from each other with the first vertical channel structure therebetween,
the horizontal channel layer includes a first sub-horizontal channel layer at least partially overlapping the first vertical channel structure in the vertical direction, a second sub-horizontal channel layer at least partially overlapping the second vertical channel structure in the vertical direction, and a third sub-horizontal channel layer at least partially overlapping the third vertical channel structure in the vertical direction, and
the first sub-horizontal channel layer mediates the second vertical channel structure with the third vertical channel structure.

19. A semiconductor device comprising:
a semiconductor substrate having a memory cell region and a connection region;
a gate stack including a plurality of word line gate layers and a plurality of insulating layers, which extend in a horizontal direction and are alternately stacked in a vertical direction on a main surface of the semiconductor substrate, the gate stack having a stair structure including a plurality of pad portions in the connection region;
an insulating block on the gate stack;
a horizontal channel layer in the connection region and arranged on the insulating block;
an interlayer insulating layer on the horizontal channel layer;
a plurality of upper gate layers in the connection region, extending on the interlayer insulating layer in a first horizontal direction, and arranged in parallel with each other in a second horizontal direction crossing the first horizontal direction;
a string selection line gate layer in the memory cell region and at a same vertical level as the plurality of upper gate layers on the insulating block; and
a plurality of vertical channel structures passing through the interlayer insulating layer and the plurality of upper gate layers and contacting the horizontal channel layer.

20. The semiconductor device of claim 19, wherein the horizontal channel layer has a greater planar area than the plurality of vertical channel structures and extends in a direction in which the plurality of vertical channel structures are arranged.
